(19) United States
(12) Patent Application Publication
(10) Pub. No.: US 2025/0022989 A1
(43) Pub. Date: Jan. 16, 2025

(54) DISPLAY PANEL AND METHOD FOR MANUFACTURING THE SAME

(71) Applicant: PlayNitride Display Co., Ltd., Zhunan Township (TW)

(72) Inventors: Hio-Kun SI, Zhunan Township (TW); Sheng-Yuan SUN, Zhunan Township (TW); Po-Wei CHIU, Zhunan Township (TW); Hoong Lien LAI, Zhunan Township (TW)

(73) Assignee: PlayNitride Display Co., Ltd., Zhunan Township (TW)

(21) Appl. No.: 18/477,362

(22) Filed: Sep. 28, 2023

(30) Foreign Application Priority Data
Jul. 14, 2023 (TW) 112126326

(51) Int. Cl. H01L 33/50; H01L 25/075; H01L 33/56

(52) U.S. Cl. CPC H01L 33/502; H01L 25/0753; H01L 33/56

(57) ABSTRACT

A display panel is provided. The display panel includes a carrier having a patterned region that is disposed on the surface of the carrier and corresponds to a plurality of sub-pixel structures. The display panel also includes an encapsulation material layer disposed on a portion of the pattered region. The display panel further includes a first color conversion layer disposed on the portion of the encapsulation material layer and includes a plurality of first color conversion capsules. The first color conversion capsules are configured to convert the light-emitting color of the sub-pixel structures into a first light-emitting color. Partial surfaces of some first color conversion capsules are exposed from the encapsulation material layer.

### CROSS REFERENCE TO RELATED APPLICATIONS

This application claims priority of Taiwan Patent Application No. 112126326, filed on Jul. 14, 2023, the entirety of which is incorporated by reference herein.

### BACKGROUND OF THE INVENTION

### Field of the Invention

The embodiment of the present disclosure relates to a display panel, and in particular to a display panel that includes multiple color conversion capsules and a method for manufacturing the same.

### Description of the Related Art

With the advancement of optoelectronic technology, many optoelectronic components are gradually moving towards miniaturization. Micro LEDs (mLEDs/uLEDs) have several advantages over organic light-emitting diodes (OLED), such as high efficiency, longer life, and they are made of materials that are relatively stable and not easily affected by the environment. Therefore, displays using micro LEDs arranged in arrays are gradually gaining attention on the market.

Quantum dots (QD) are semiconductor particles composed of elements such as Group II-VI or Group III-V, with sizes generally between a few nanometers and tens of nanometers. The light-emitting color of quantum dot materials can be adjusted through its size, structure, or composition, and used in conjunction with components such as light filters to achieve high-purity color conversion performance. Hence, they are widely used in display panels and devices.

However, when using quantum dot materials as the color conversion layer of the display panel, it is necessary to mix the quantum dot materials with photoresist and seal the display panel with cover plates, glue frames, etc., to prevent the mixed liquid from overflowing or the quantum dot materials from being affected by water and air and deteriorating, thereby increasing the manufacturing cost. As pixel sizes shrink, the nozzle for ejecting quantum dot materials and photoresist shrinks, only allowing low concentrations of quantum dot materials in the mixed liquid, resulting in a limitation on breakthroughs in light (color) conversion efficiency.

In addition, since the mixed liquid of quantum dot materials and photoresist is contained in the trenches formed by the banks of the patterned array, increasing the height of the banks can accommodate more mixed liquid to improve conversion efficiency. However, due to limitations in exposure and development technologies, it is difficult to form banks of sufficient height. Therefore, the application of quantum dot materials to achieve color conversion in micro LED display panels/devices still faces various challenges.

### BRIEF SUMMARY OF THE INVENTION

According to some embodiments of the present disclosure, a display panel and a method for manufacturing the same are provided. The display panel includes a color conversion layer disposed on an encapsulation material layer. As the color conversion layer includes multiple color conversion capsules, and the color conversion capsules may adhere to the encapsulation material layer, there is no need to mix the color conversion capsules with photoresist. This allows forming a high-density/high-concentration color conversion layer to improve the light (color) conversion efficiency of the display panel.

Hence, there is no need to increase the height of the banks to achieve the required light (color) conversion efficiency, thereby effectively reducing the difficulty of manufacturing the display panel. In addition, after manufacturing, the remaining unused color conversion capsules may be recycled and reused, thus avoiding waste and reducing overall manufacturing and environmental protection costs.

The embodiments of the present disclosure include a display panel. The display panel includes a carrier having a patterned region that is disposed on the surface of the carrier and corresponds to a plurality of sub-pixel structures. The display panel also includes an encapsulation material layer disposed on a portion of the pattered region. The display panel further includes a first color conversion layer disposed on the portion of the encapsulation material layer and includes a plurality of first color conversion capsules. The first color conversion capsules are configured to convert the light-emitting color of the sub-pixel structures into a first light-emitting color. Partial surfaces of some first color conversion capsules are exposed from the encapsulation material layer.

The embodiments of the present disclosure also include a method for manufacturing a display panel. The method for manufacturing the display panel includes the following steps. A carrier is provided. The carrier has a patterned region that is disposed on the surface of the carrier and corresponds to a plurality of sub-pixel structures. An encapsulation material layer with adhesion is formed on a portion of the patterned region. Multiple first color conversion capsules are provided on the surface of the carrier. The first color conversion capsules are configured to convert the light-emitting color of the sub-pixel structures into a first light-emitting color. Some first color conversion capsules are adhered on the encapsulation material layer. The first color conversion capsules adhered on the encapsulation material layer have partial surfaces exposed from the encapsulation material layer.

### BRIEF DESCRIPTION OF THE DRAWINGS

Aspects of the embodiments of the present disclosure can be understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 to FIG. 7 are partial top views illustrating various stages of manufacturing a display panel according to some embodiments of the present disclosure.

FIG. 8A to FIG. 8H are partial cross-sectional views illustrating various stages in which the color conversion capsules are adhered to the encapsulation material layer according to some embodiments of the disclosure.

FIG. 9 is a partial cross-sectional view illustrating a display panel according to some embodiments of the disclosure.

### DETAILED DESCRIPTION OF THE INVENTION

The following disclosure provides many different embodiments, or examples, for implementing different features of the subject matter provided. Specific examples of components and arrangements are described below to simplify the present disclosure. These are, of course, merely examples and are not intended to be limiting. For example, a first feature is formed on a second feature in the description that follows may include embodiments in which the first feature and second feature are formed in direct contact, and may also include embodiments in which additional features may be formed between the first feature and second feature, so that the first feature and second feature may not be in direct contact.

It should be understood that additional steps may be implemented before, during, or after the illustrated methods, and some steps might be replaced or omitted in other embodiments of the illustrated methods.

Furthermore, spatially relative terms, such as “beneath,” “below,” “lower,” “on,” “above,” “upper” and the like, may be used herein for ease of description to describe one element or feature's relationship to other elements or features as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In the present disclosure, the terms “about,” “approximately” and “substantially” typically mean+/−20% of the stated value, more typically +/−10% of the stated value, more typically +/−5% of the stated value, more typically +/−3% of the stated value, more typically +/−2% of the stated value, more typically +/−1% of the stated value and even more typically +/−0.5% of the stated value. The stated value of the present disclosure is an approximate value. That is, when there is no specific description of the terms “about,” “approximately” and “substantially”, the stated value includes the meaning of “about,” “approximately” or “substantially”.

Unless otherwise defined, all terms (including technical and scientific terms) used herein have the same meaning as commonly understood by one of ordinary skill in the art to which this disclosure belongs. It should be understood that terms such as those defined in commonly used dictionaries should be interpreted as having a meaning that is consistent with their meaning in the context of the relevant art and will not be interpreted in an idealized or overly formal sense unless expressly so defined in the embodiments of the present disclosure.

The present disclosure may repeat reference numerals and/or letters in following embodiments. This repetition is for the purpose of simplicity and clarity and does not in itself dictate a relationship between the various embodiments and/or configurations discussed.

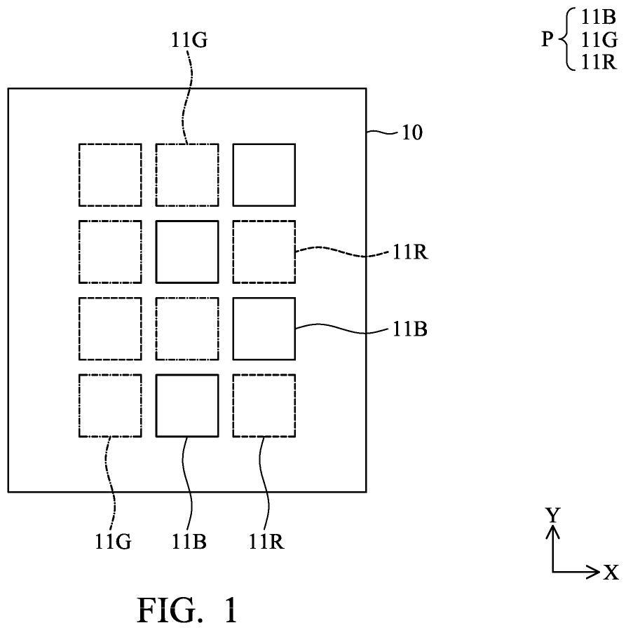

FIG. 1 to FIG. 7 are partial top views illustrating various stages of manufacturing a display panel 100 according to some embodiments of the present disclosure. It should be noted that some components of the display panel 100 have been omitted in FIG. 1 to FIG. 7 for the sake of brevity.

Referring to FIG. 1, in some embodiments, a carrier 10 that has a patterned region P is provided. The patterned region P is on the surface of the carrier 10 and corresponds to multiple sub-pixel structures 11R, sub-pixel structures 11G, and sub-pixel structures 11B. As shown in FIG. 1, multiple sub-pixel structures 11R, sub-pixel structures 11G, and sub-pixel structures 11B may be arranged as an array, but the present disclosure is not limited thereto.

In some embodiments, the carrier 10 is a display substrate, a light-emitting substrate, a substrate with functional components such as thin-film transistors (TFT) or integrated circuits (IC), or other types of circuit boards, and the sub-pixel structures 11R, the sub-pixel structures 11G, and the sub-pixel structures 11B are disposed on the carrier 10 and electrically connected to the carrier 10. The carrier 10 may be a rigid circuit substrate, for example, which may include elemental semiconductors (e.g., silicon or germanium), compound semiconductors (e.g., silicon carbide (SiC), gallium arsenide (GaAs), indium arsenide (InAs), or indium phosphide (InP)), alloy semiconductors (e.g., SiGe, SiGeC, GaAsP, or GaInP), any other suitable semiconductor, or a combination thereof. Alternatively, the carrier 10 may also be a flexible circuit substrate, a semiconductor-on-insulator (SOI) substrate, or other similar substrates.

In addition, the carrier 10 may include various conductive components (e.g., conductive lines or conductive vias). For example, the aforementioned conductive components may include aluminum (Al), copper (Cu), tungsten (W), their respective alloys, any other suitable conductive material, or a combination thereof. In the example where the carrier 10 is a display substrate, the carrier 10 may be further connected to an external circuit (not shown) to drive and operate the sub-pixel structures 11R, 11G, and 11B.

In some other embodiments, the carrier 10 is a temporary template. For example, the carrier 10 may include a plastic substrate, a ceramic substrate, a glass substrate, a sapphire substrate, or any other substrate without circuitry. In these examples, light-emitting elements may be manufactured in the regions on the carrier 10 that correspond to the sub-pixel structures 11R, the sub-pixel structures 11G, and the sub-pixel structures 11B (for example, through a epitaxial growth process), but the present disclosure is not limited thereto.

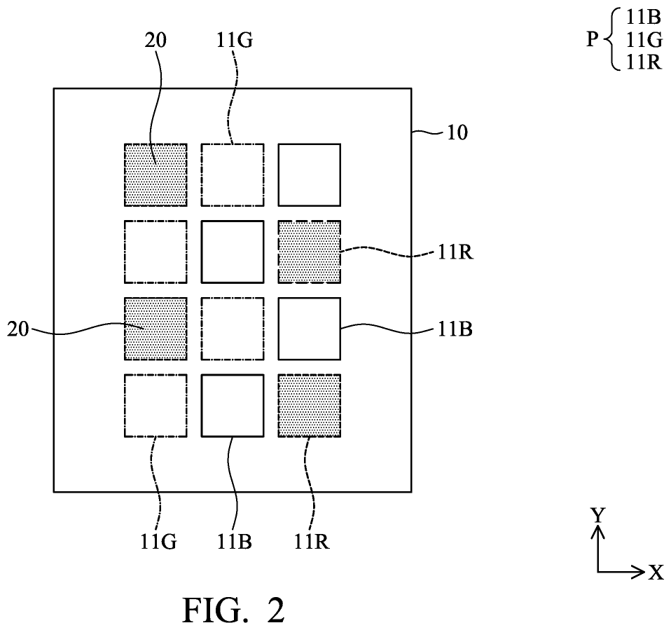

Referring to FIG. 2, in some embodiments, an encapsulation material layer 20 with adhesiveness is formed on a portion of the patterned region P. More specifically, the encapsulation material layer 20 is formed on the region of the patterned region P that corresponds to the sub-pixel structure 11R. For example, the encapsulation material layer 20 may be an adhesive transparent photoresist, which may include silicon oxide (SiOₓ) or titanium oxide (TiO₂), but the present disclosure is not limited thereto. The encapsulation material layer 20 may be formed by a coating process and a patterning process.

Specifically, the aforementioned adhesive transparent photoresist may be coated on the surface of the carrier 10. Then, a pre-curing process is carried out on the transparent photoresist disposed on the local region (i.e., the region that corresponds to the patterned structures 11R formed later). For example, the composition of the transparent photoresist may be adjusted (e.g., by controlling the content of the photo-initiator), the heating time or temperature may be controlled (e.g., pre-exposure baking or post-exposure baking (PEB)), the curing time may be controlled (e.g., exposure time) and/or the UV dosage may be controlled (f e.g., exposure intensity) to achieve pre-curing of the local region. After pre-curing, the transparent photoresist is patterned, so that the transparent photoresist on the local region (i.e., the region that corresponds to the patterned structures 11R formed later) will not be removed by washing, but is not completely cured (i.e., retains stickiness), thereby forming an encapsulation material layer 20 on the region of the patterned region P that corresponds to the sub-pixel structures 11R.

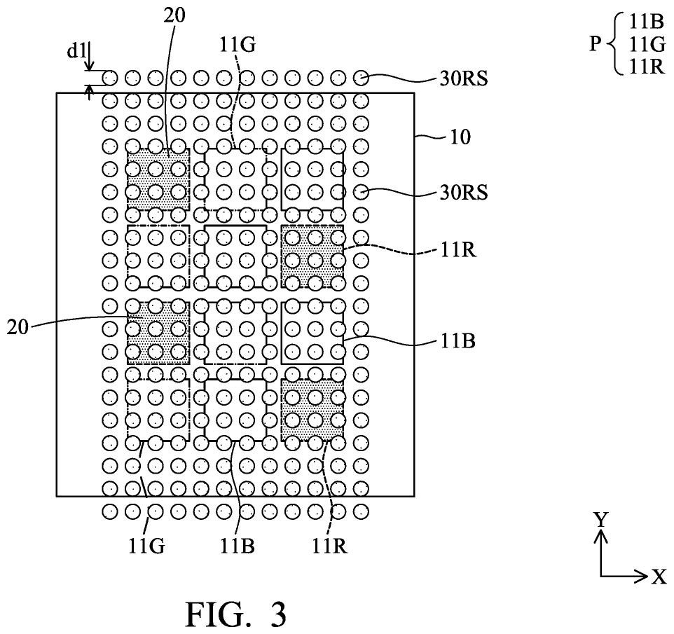

Referring to FIG. 3, multiple color conversion capsules 30RS are provided on the surface of the carrier 10, and the color conversion capsules 30RS are configured to convert the light-emitting color of the sub-pixel structures 11R into red. The color conversion capsule 30RS includes red quantum dots, and it also includes polystyrene (PS), polyethylene (PE), acrylic resin, silicone (e.g., glass), polycarbonate (PC), a similar material, a mixture thereof, or a copolymer thereof.

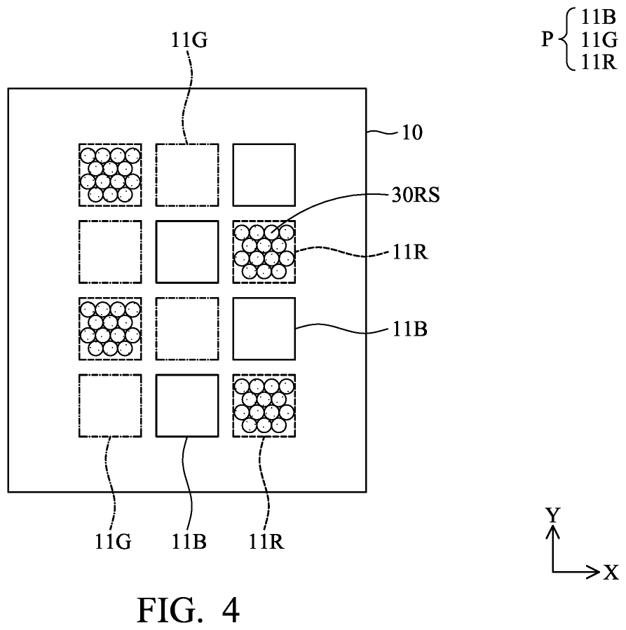

Referring to FIG. 4, some color conversion capsules 30RS are adhered to the region of the encapsulation material layer 20 that corresponds to the sub-pixel structures 11R. Subsequently, the color conversion capsules 30RS not adhered to the encapsulation material layer 20 are removed from the carrier 10. For example, the color conversion capsules 30RS not adhered to the encapsulation material layer 20 may be removed from the carrier 10 by oscillation, inversion, blowing, fluid suspension, or any other similar procedure, but the present disclosure is not limited thereto.

After the color conversion capsules 30RS which are not be adhered are removed, the encapsulation material layer 20 on the patterned region P that is corresponds to the sub-pixel structures 11R is cured, making the encapsulation material layer 20 in this region non-adhesive after curing. For example, a thermal curing process, a photo curing process, UV curing, or any other similar process may be performed to cure the encapsulation material layer 20, but the present disclosure is not limited thereto.

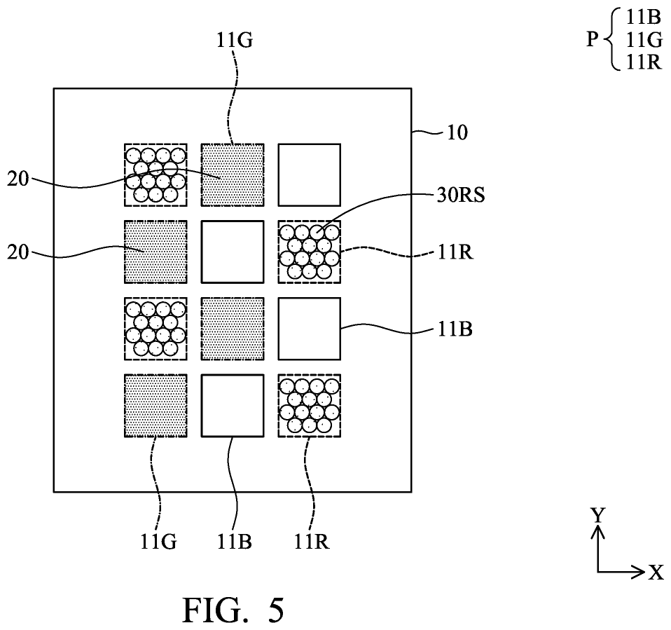

Since the encapsulation material layer 20 on the sub-pixel structures 11R is fully cured, the color conversion capsules 30RS are fixed within the region of the sub-pixel structures 11R. Referring to FIG. 5, the above steps are repeated to form an encapsulation material layer 20 with adhesiveness again on the region of the patterned region P that corresponds to the sub-pixel structures 11G. The encapsulation material layer 20 may be formed on the region that corresponds to the sub-pixel structures 11G in the same way as mentioned above, but the present disclosure is not limited thereto.

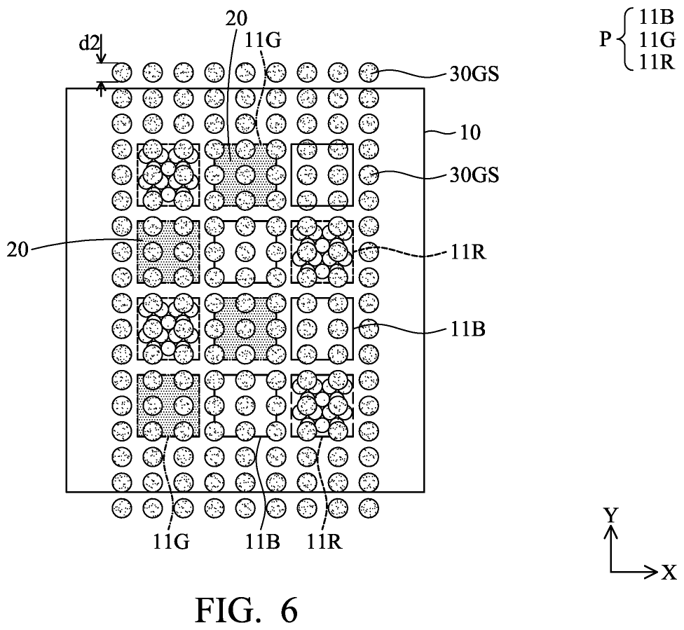

Referring to FIG. 6, multiple color conversion capsules 30GS are provided on the surface of the carrier 10, and the color conversion capsules 30GS are configured to convert the light-emitting color of the sub-pixel structures 11G into green, but the formation order, the color of the sub-pixel structures, or the color and number of color conversion capsules shown in FIG. 3 to FIG. 6 may all be freely adjusted. Moreover, in some embodiments, the light-emitting color converted by the color conversion capsules may also have wavelengths other than standard red or green light, for example, yellow.

In this embodiment, the color conversion capsules 30GS and the color conversion capsules 30RS respectively convert the sub-pixel structures 11G and the sub-pixel structures 11R into green and red. The color conversion capsule 30GS includes materials similar to or the same as the color conversion capsule 30RS, which will not be repeated here.

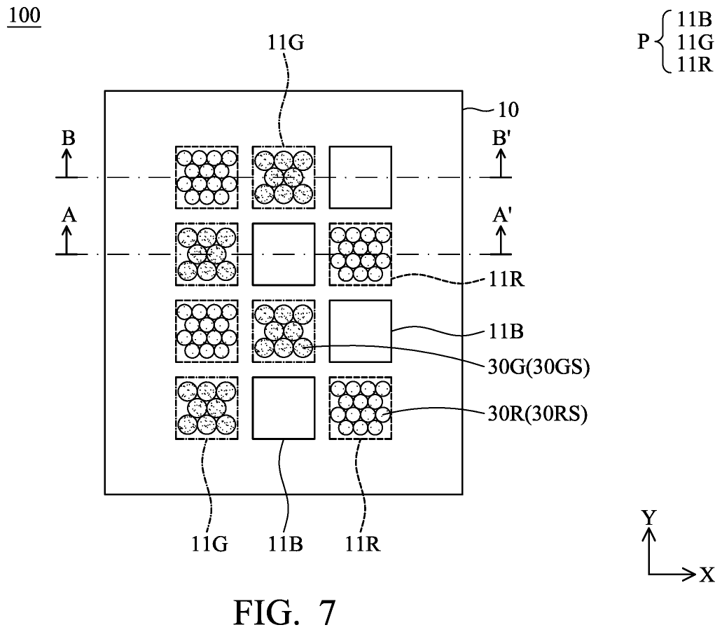

Referring to FIG. 7, some color conversion capsules 30GS are adhered to the region of the encapsulation material layer 20 that corresponds to the sub-pixel structures 11G, and then the color conversion capsules 30GS not adhered to the encapsulation material layer 20 are removed from the carrier 10. Similarly, the color conversion capsules 30GS not adhered to the encapsulation material layer 20 may be removed from the carrier 10 by oscillation, inversion, blowing, fluid suspension, or any other similar procedure.

In addition, in some embodiments, the encapsulation material layer 20 on the patterned region P that corresponds to the sub-pixel structures 11G is cured, so that the encapsulation material layer 20 in this region is non-adhesive after curing. The process of curing the encapsulation material layer 20 is as mentioned above and will not be repeated here.

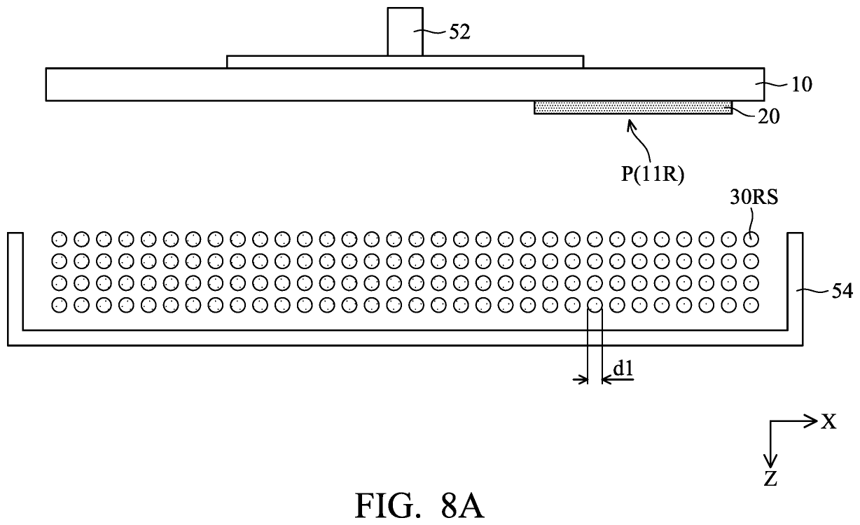

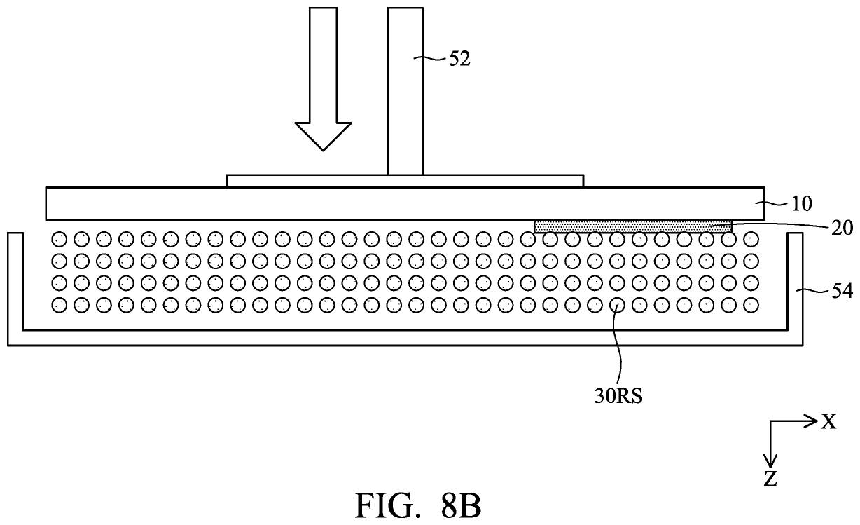

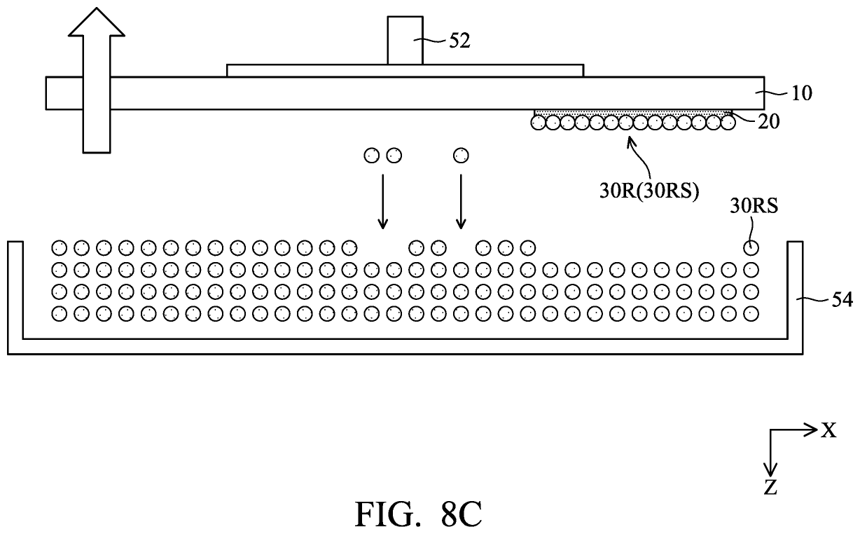

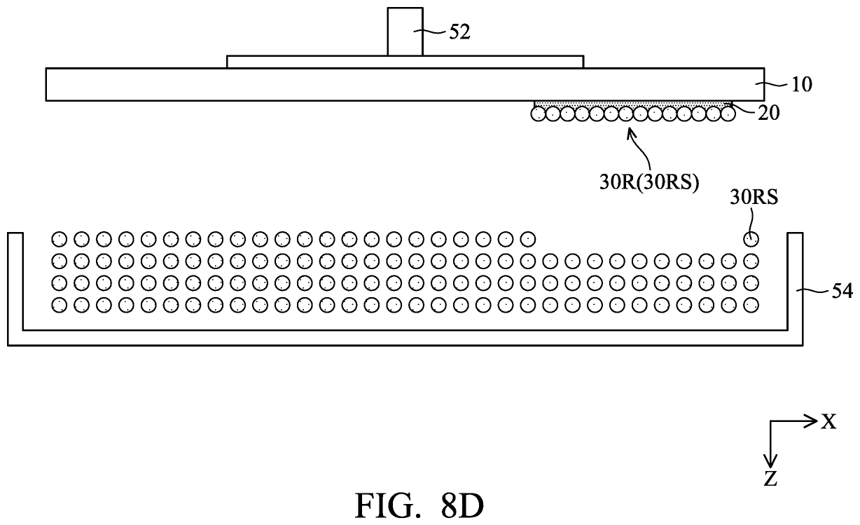

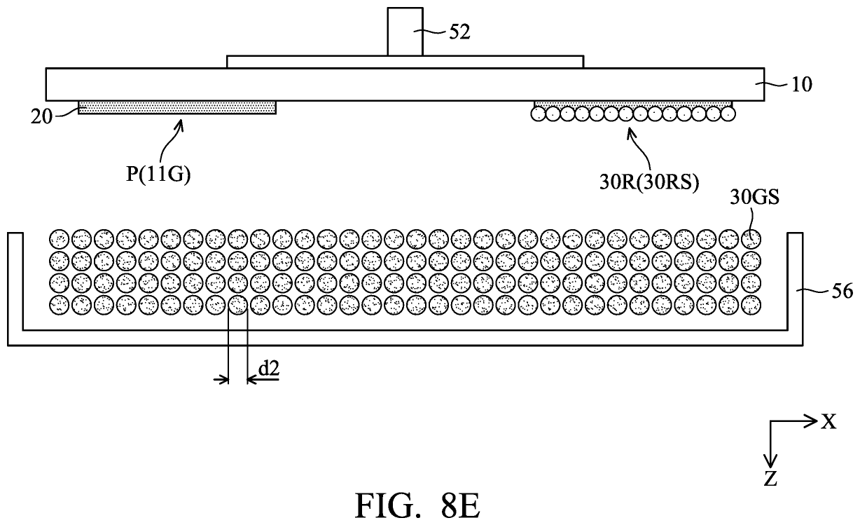

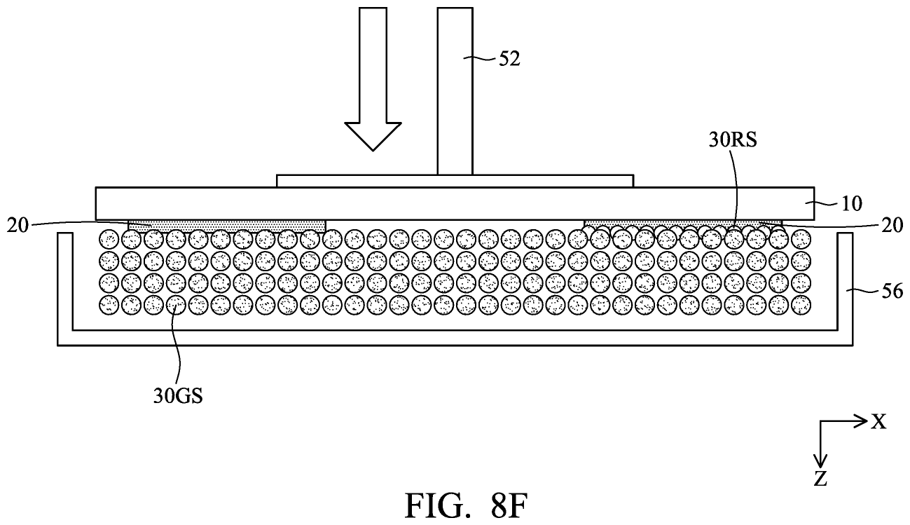

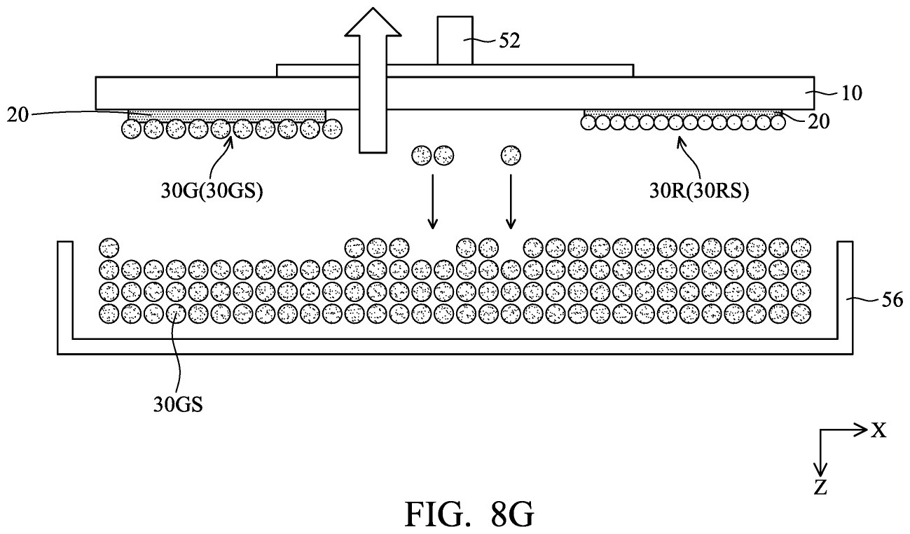

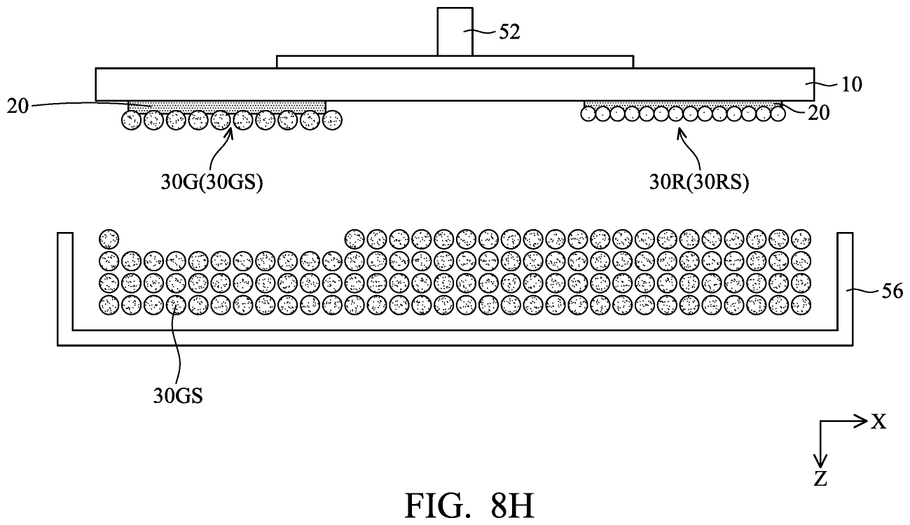

FIG. 8A to FIG. 8H are partial cross-sectional views illustrating various stages in which the color conversion capsules 30RS and the color conversion capsules 30GS are adhered to the encapsulation material layer 20 according to some embodiments of the disclosure. For example, the partial cross-sectional views shown in FIG. 8A to FIG. 8H may correspond to the cross-section cut by line A-A′ in FIG. 7. Similarly, some components have been omitted in FIG. 8A to FIG. 8H for the sake of brevity.

Referring to FIG. 8A, the carrier 10 that includes the encapsulation material layer 20 is inverted and adsorbed on the fixture 52. For example, the carrier 10 may be adsorbed on the fixture 52 by a vacuum adsorption method. In this embodiment, the encapsulation material layer 20 is disposed on the patterned region P of the carrier 10 and corresponds to the region where the patterned structures 11R are formed subsequently. The encapsulation material layer 20 may be formed by the aforementioned coating process and patterning process.

Then, the fixture 52 that adsorbs the carrier 10 is moved to above the cavity 54 that includes multiple color conversion capsules 30RS. In this embodiment, the color conversion capsules 30RS are spherical and have a diameter d1. For example, the diameter d1 may range from 20 nm to 150 nm, such as between 50 nm and 100 nm, but the present disclosure is not limited thereto.

Then, referring to FIG. 8B, the fixture 52 is moved (in the +Z direction for example, as illustrated in FIG. 8B) to bring the carrier 10 and the encapsulation material layer 20 close to the cavity 54, and the carrier 10 and the encapsulation material layer 20 are brought into contact with multiple color conversion capsules 30RS.

Then, referring to FIG. 8C and FIG. 8D, the fixture 52 is moved (in the −Z direction for example, as shown in FIG. 8C) to move the carrier 10 and the encapsulation material layer 20 away from the cavity 54. As shown in FIG. 8C, some color conversion capsules 30RS adhere to the encapsulation material layer 20, and the color conversion capsules 30RS that are not adhered to the encapsulation material layer 20 fall back into the cavity 54 (i.e., are recycled).

After the color conversion capsules 30RS are adhered to the encapsulation material layer 20, a curing process may be performed again to fully cure the encapsulation material layer 20. At this stage, the curing process may include a hard-bake process, for example, and the hard-bake process may be performed under conditions of 120° C. to 200° C., but the present disclosure is not limited thereto. As shown in FIG. 8C and FIG. 8D, multiple color conversion capsules 30RS stack on the encapsulation material layer 20 to form a color conversion layer 30R.

Next, referring to FIG. 8E, in this embodiment, the encapsulation material layer 20 is disposed on the patterned region P of the carrier 10 and corresponds to the region where the patterned structures 11G are formed later. For example, the encapsulation material layer 20 may be formed by a coating process and a patterning process. The examples of the relevant processes are as mentioned above and will not be repeated here.

Then, the fixture 52 that adsorbs the carrier 10 is moved to above another cavity 56 that includes multiple color conversion capsules 30GS. In some embodiments, the volume of each color conversion capsule 30GS is larger than the volume of each color conversion capsule 30RS. In this embodiment, the color conversion capsules 30GS are spherical and have a diameter d2. For example, the diameter d2 may range from 20 nm to 150 nm, or between 50 nm and 100 nm. Moreover, in this embodiment, the diameter d2 of the color conversion capsule 30GS is larger than the diameter d1 of the color conversion capsule 30RS, but the present disclosure is not limited thereto.

Then, referring to FIG. 8F, the fixture 52 is moved (in the +Z direction for example, as illustrated in FIG. 8F) to bring the carrier 10 and the encapsulation material layer 20 close to the cavity 56, and the carrier 10 and the encapsulation material layer 20 are brought into contact with multiple color conversion capsules 30GS.

Then, referring to FIG. 8G and FIG. 8H, the fixture 52 is moved (in the −Z direction for example, as illustrated in FIG. 8G) to move the carrier 10 and the encapsulation material layer 20 away from the cavity 56. As shown in FIG. 8H, some color conversion capsules 30GS adhere to the encapsulation material layer 20, and the color conversion capsules 30GS that are not adhered to the encapsulation material layer 20 fall back into the cavity 56 (i.e., are recycled).

Furthermore, since the diameter d2 of the color conversion capsule 30GS is larger than the diameter d1 of the color conversion capsule 30RS, during the period of adhering the color conversion capsule 30GS to the encapsulation material layer 20, it may prevent the color conversion capsule 30GS from being stuck in (or adhering to) the gaps between the multiple color conversion capsules 30RS that have already adhered to the encapsulation material layer 20. It may be understood from the above description that the size difference between the diameters d2 and d1 may prevent different color conversion capsules from mixing in the same patterned structure. Therefore, as long as the color conversion capsules with smaller diameters are adhered before the ones with larger diameters, their conversion colors do not affect the order in which they are adhered.

Similarly, after the color conversion capsules 30GS are adhered to the encapsulation material layer 20, a curing process may be performed again to fully cure the encapsulation material layer 20. As shown in FIG. 8G and FIG. 8H, multiple color conversion capsules 30GS stack on the encapsulation material layer 20 to form a color conversion layer 30G.

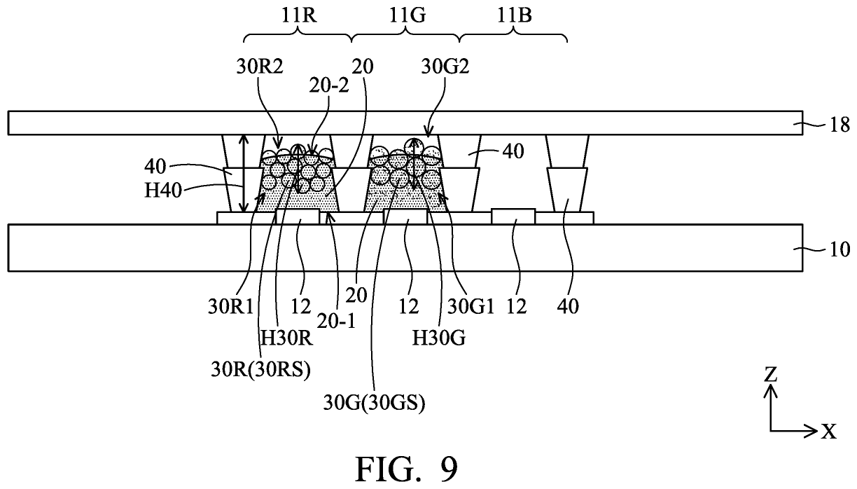

FIG. 9 is a partial cross-sectional view illustrating a display panel 100 according to some embodiments of the disclosure. For example, the partial cross-sectional view shown in FIG. 9 may correspond to the cross-section cut by line B-B′ in FIG. 7, but the present disclosure is not limited thereto. Similarly, some components of the display panel 100 have been omitted in FIG. 9 for the sake of brevity.

Referring to FIG. 7 and FIG. 9 together, the display panel 100 includes a carrier 10 that has a patterned region P. The patterned region P is disposed on the surface of the carrier 10 and corresponds to multiple sub-pixel structures 11R, sub-pixel structures 11G, and sub-pixel structures 11B. The display panel 100 also includes an encapsulation material layer 20 that is disposed on a first portion of the patterned region P (for example, corresponding to the sub-pixel structures 11R). The display panel 100 further includes a color conversion layer 30R disposed on the encapsulation material layer 20 on the first portion and includes multiple color conversion capsules 30RS. The color conversion capsules 30RS are configured to convert the light-emitting color of the sub-pixel structures 11R to a first light-emitting color (e.g., red). As shown in FIG. 9, in this embodiment, partial surfaces of some color conversion capsules 30RS are exposed from the encapsulation material layer 20.

As shown in FIG. 9, the color conversion capsules 30RS are stacked on the encapsulation material layer 20. The color conversion layer 30R has a first side 30R1 connected to the encapsulation material layer 20, and it has a second side 30R2 that is separate from the encapsulation material layer 20, and partial surfaces of some color conversion capsules 30RS that are exposed from the encapsulation material layer 20 are disposed on the second side 30R2. In addition, in some embodiments, the color conversion capsules 30RS are closely adjacent to each other.

As shown in FIG. 9, the encapsulation material layer 20 is also disposed on a second portion of the patterned region P (for example, corresponding to the sub-pixel structures 11G), and the display panel 10 further includes a color conversion layer 30G that is disposed on the encapsulation material layer 20 on the second portion and includes multiple color conversion capsules 30GS. The color conversion capsules 30GS are configured to convert the light-emitting color of the sub-pixel structures 11G to a second light-emitting color (e.g., green). As shown in FIG. 9, in this embodiment, partial surfaces of some color conversion capsules 30GS are exposed from the encapsulation material layer 20.

Similarly, as shown in FIG. 9, the color conversion capsules 30GS are stacked on the encapsulation material layer 20. The color conversion layer 30G has a first side 30G1 connected to the encapsulation material layer 20, and it has a second side 30G2 that is separate from the encapsulation material layer 20, and the partial surfaces of some color conversion capsules 30GS that are exposed from the encapsulation material layer 20 are disposed on the second side 30G2. In addition, in some embodiments, the color conversion capsules 30GS are closely adjacent to each other.

In some embodiments, the encapsulation material layer 20 includes a cured adhesive photoresist material. The encapsulation material layer 20 has a third side 20-1 that is close to the carrier 10, and it has a fourth side 20-2 that is separate from the carrier 10, and the color conversion capsules 30RS (and the color conversion capsules 30GS) are adhered and fixed to the fourth side 20-2.

As shown in FIG. 9, in some embodiments, the display panel 100 further includes a light-absorbing layer 40 disposed on the carrier 10 and may be an array structure that surrounds each sub-pixel structure (11R, 11G, and 11B) of the patterned region P, thereby separating the sub-pixel structures (11R, 11G, and 11B) on the surface of the carrier 10. For example, the light-absorbing layer 40 may be a photoresist (e.g., a black photoresist or other appropriate non-transparent photoresist), ink (e.g., black ink or any other appropriate non-transparent ink), molding compound (e.g., black molding compound or any other appropriate non-transparent molding compound), solder mask (e.g., black solder mask or any other appropriate non-transparent solder mask), epoxy resin, any other appropriate material, or a combination thereof. In some embodiments, the light-absorbing layer 40 may include photocurable materials, thermosetting materials, or a combination thereof. Furthermore, the light-absorbing layer 40 may be formed by a coating process and a patterning process, but the present disclosure is not limited thereto.

It should be noted that the processes for manufacturing display panel 100 shown in FIG. 1 to FIG. 7 and FIG. 8A to FIG. 8H have omitted the light-absorbing layer 40. In some embodiments, the light-absorbing layer 40 is first formed on the carrier 10 to define different sub-pixel structures 11R, sub-pixel structures 11G, and sub-pixel structures 11B. That is, in the processes shown in FIG. 8A to FIG. 8H, when the operation fixture 52 approaches the cavity 54 or 56, the color conversion capsules enter the array structure formed by the light-absorbing layer 40 and adhere to the encapsulation material layer 20 between the light-absorbing layer 40.

As shown in FIG. 9, in some embodiments, in the thickness direction (i.e., the Z direction in FIG. 9) of the carrier 10, the heights H30R and H30G of the color conversion layers 30R and the color conversion layers 30G are less than or equal to the height H40 of the light-absorbing layer 40. Here, the heights H30R and H30G are defined as the maximum heights of the color conversion layers 30R and the color conversion layers 30G respectively.

Furthermore, as shown in FIG. 9, in some embodiments, the display panel 100 includes multiple light-emitting chips 12, and the color conversion layers 30R and the color conversion layers 30G are correspondingly disposed on the light-emitting chips 12. For example, the light-emitting chip 12 may emit blue light. The sub-pixel structures 11R convert the blue light into red light by the color conversion capsules 30RS of the color conversion layer 30R; the sub-pixel structures 11G convert the blue light into green light by the color conversion capsules 30GS of the color conversion layer 30G. The light-emitting chips 12 that do not correspond to the color conversion layers 30R or the color conversion layers 30G still maintain blue light, but the present disclosure is not limited thereto. Different color conversion layers may be disposed on the light-emitting chips 12 according to actual needs. In some embodiments, the display panel 100 includes a cover plate 18 disposed above the light-emitting chips 12 (above the color conversion layers 30R and the color conversion layers 30G). For example, the cover plate 18 may include transparent glass, but the present disclosure is not limited thereto. Furthermore, filling materials (not shown) may be disposed in other gaps between the cover plate 18 and the carrier 10.

As noted above, in the embodiments of the present disclosure, quantum dots are already encapsulated in the color conversion capsules, so the display panel of the embodiments of the present disclosure does not need to set an additional quantum dot protection layer (e.g., a gel frame). In addition, the proportion of materials in the color conversion capsules may be customized, the concentration of quantum dots is not limited by the equipment, and it is not necessary to make a high bank to accommodate the mixture that includes quantum dots. Moreover, unused quantum dots (color conversion capsules) may be recycled. Since the color conversion capsules are closely arranged due to being adhered to the encapsulation material layer, compared to traditional quantum dots loosely distributed in the mixture, the light/color conversion efficiency will be greatly improved.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure. Therefore, the scope of protection should be determined through the claims. In addition, although some embodiments of the present disclosure are disclosed above, they are not intended to limit the scope of the present disclosure.

Reference throughout this specification to features, advantages, or similar language does not imply that all of the features and advantages that may be realized with the present disclosure should be or are in any single embodiment of the disclosure. Rather, language referring to the features and advantages is understood to mean that a specific feature, advantage, or characteristic described in connection with an embodiment is included in at least one embodiment of the present disclosure. Thus, discussions of the features and advantages, and similar language, throughout this specification may, but do not necessarily, refer to the same embodiment.

Furthermore, the described features, advantages, and characteristics of the disclosure may be combined in any suitable manner in one or more embodiments. One skilled in the relevant art will recognize, in light of the description herein, that the disclosure can be practiced without one or more of the specific features or advantages of a particular embodiment. In other instances, additional features and advantages may be recognized in certain embodiments that may not be present in all embodiments of the disclosure.

What is claimed is:

1. A display panel, comprising:
a carrier having a patterned region that is disposed on a surface of the carrier and corresponds to a plurality of sub-pixel structures;
an encapsulation material layer disposed on a portion of the patterned region; and
a first color conversion layer disposed on the portion of the encapsulation material layer and comprises a plurality of first color conversion capsules that are configured to convert a light-emitting color of the sub-pixel structures into a first light-emitting color;
wherein partial surfaces of some of the first color conversion capsules are exposed from the encapsulation material layer.

2. The display panel as claimed in claim 1, wherein the encapsulation material layer is also disposed on another portion of the patterned region, and the display panel further comprises:
a second color conversion layer disposed on the another portion of the encapsulation material layer and comprises a plurality of second color conversion capsules that are configured to convert the light-emitting color of the sub-pixel structures into a second light-emitting color;
wherein partial surfaces of some of the second color conversion capsules are exposed from the encapsulation material layer.

3. The display panel as claimed in claim 2, wherein the first light-emitting color is different from the second light-emitting color, and a volume of each of the second color conversion capsules is larger than a volume of each of the first color conversion capsules.

4. The display panel as claimed in claim 1, wherein the first color conversion capsules are stacked on the encapsulation material layer, the first color conversion layer has a first side connected to the encapsulation material layer and a second side that is separate from the encapsulation material layer, and the partial surfaces of some of the second color conversion capsules exposed from the encapsulation material layer are disposed on the second side.

5. The display panel as claimed in claim 1, wherein the encapsulation material layer comprises a cured adhesive photoresist material, and the first color conversion capsules are adhered and fixed to a side of the encapsulation material layer that is separate from the carrier.

6. The display panel as claimed in claim 5, wherein the first color conversion capsules are closely adjacent to each other.

7. The display panel as claimed in claim 1, further comprising:
a light-absorbing layer disposed on the carrier and surrounding the patterned region, wherein the light-absorbing layer separates the sub-pixel structures on the surface of the carrier.

8. The display panel as claimed in claim 7, wherein in a thickness direction of the carrier, a height of the first color conversion layer is less than or equal to a height of the light-absorbing layer.

9. The display panel as claimed in claim 1, wherein the first color conversion capsules comprise polystyrene, ethylene polymer, acrylic resin, silicon oxide resin, carbonate, a mixture thereof, or a copolymer thereof.
